(19) United States
(12) Patent Application Publication
(10) Pub. No.: US 2024/0291388 A1
(43) Pub. Date: Aug. 29, 2024

(54) Current booster

(71) Applicant: ZS Electric AB, Täby (SE)

(72) Inventor: Zoran Stanisic, Täby (SE)

(21) Appl. No.: 18/576,378

(22) PCT Filed: Jul. 7, 2022
(86) PCT No.: PCT/SE2022/050700

§ 371 Date: Jan. 4, 2024

(30) Foreign Application Priority Data
Jul. 8, 2021 (SE) 2150913-8

(51) Int. Cl. H02M 3/335; H02M 3/00; H05K 1/11; H05K 1/16

(52) U.S. Cl. CPC H02M 3/33571; H02M 3/003; H02M 3/33573; H02M 3/33592; H05K 1/115; H05K 1/165

(57) ABSTRACT

This disclosure presents a current booster circuitry (100) for providing a boosted current from a power source (30) to a load (40). The current booster circuitry (100) comprises a transformer (120), at least two input terminals (142, 144) for operatively connecting the power source (30) to at least one primary winding (122) of the transformer (120), and at least two output terminals (146, 148) for operatively connecting the load (40) in parallel to at least two secondary windings (126a, 126b) of the transformer (120). Further to this, the current booster (100) comprises a secondary side electric circuitry (130) comprising a plurality of secondary switches (131, 132, 133, 134) arranged for controlling a direction of the boosted current and arranged to connect the secondary windings (126a, 126b) to at least two output terminals (146, 148) with respective polarities of the secondary windings (126a, 126b) mutually reversed. In addition to this, a printed boar assembly, a current booster assembly, a current booster system and an equipment are presented.

### TECHNICAL FIELD

The present invention relates to current boosters and more precisely to current boosters for controlling a direction of a boosted current. In more detail, a current booster circuitry is presented in the present disclosure. Also, related printed circuit board assemblies, current booster assemblies, current booster systems and test equipment are presented.

### BACKGROUND

One of the most important tests of distributed power stability is measuring trip levels of all types of protection relays and motor switch gears. The trip levels may be extremely high, in some cases above several thousands of amperes. Generating such high currents in a range of thousands of ampere typically requires heavy and expensive test equipment. This test equipment is generally difficult to handle and, in addition, transport, and may cause inconvenience and potential work hazards for personnel handling the equipment. The same drawbacks may be present during resistance testing of some equipment. For example, it is common that a very high DC current level must be generated, producing measurable voltage drop level across a device under test (DUT) which, divided by generated current value, will provide the wanted resistance. A high injected current may have the ability to overcome connection issues and oxidation on terminals, where a lower current may produce false readings under these conditions. High DC currents are generally also generated in high voltage circuit breaker contacts when performing static and dynamic resistance measurement.

For the above reason, test equipment is, in many cases, constructed for injecting currents on the secondary side of the DUT, as much lower current levels are typically required at this side.

Unlike primary injection, test methods based on secondary side injection does not include e.g. current sensors, wiring, or other circuit breaker current carrying components in the test. This means that these components are typically not thoroughly tested and may potentially not fulfill legal and/or quality requirement. Further to this, circuit breakers that have thermal-magnetic or electromechanical trip units can only be verified for correct functioning via test methods utilizing current injection at the primary side. Also, primary current injection test through current transformers (CTs) should be conducted on all three phases simultaneously which may further significantly increase weight and complexity of the test equipment.

The existing apparatuses are consequently complex, bulky and heavy, usually used from the ground, attaching long, thick and heavy cables to the test objects, causing high losses, high power consumption and high transportation costs.

In U.S. Pat. No. 8,497,692, a device including a current source connectable to a test object is presented. The current source is a capacitor providing a current source that can be placed close to the testing object thereby reducing the need for thick and long power cables. However, this device only provides DC and is not suitable for generating AC.

### SUMMARY

It is in view of the above and other considerations that embodiments of the present invention has been made. The present disclosure recognizes the fact that there is a need for highly portable and light weight device, used for primary and/or secondary testing with capability for continuous generating of both a high direct current, DC, and/or an alternating current, AC, in the range of thousands of amperes.

An object of the present invention is therefore to provide a new type of current booster which is improved over prior art and which eliminates or at least mitigates the drawbacks discussed above. More specifically, an object of the invention is to provide a current booster that is light weight, portable and capable of providing a boosted current to a load in two directions. These objects are achieved by the technique set forth in the appended independent claims with preferred embodiments defined in the dependent claims related thereto.

In a first aspect, a current booster circuitry for providing a boosted current from a power source to a load is presented. The current booster circuitry comprises a transformer, at least two input terminals for operatively connecting the power source to at least one primary winding of the transformer, and at least two output terminals for operatively connecting the load in parallel to at least two secondary windings of the transformer. Further to this, the current booster comprises a secondary side electric circuitry which in turn comprises a plurality of secondary switches arranged for controlling a direction of the boosted current and arranged to connect the secondary windings to at least two output terminals with respective polarities of the secondary windings mutually reversed. Wherein said plurality of secondary switches comprises at least a first secondary switch arranged to connect a positive terminal of a first secondary winding of said at least two secondary windings to a first output terminal connectable to the load, a second secondary switch arranged to connect a negative terminal of the first secondary winding of said at least two secondary windings to a second output terminal connectable to the load, a third secondary switch arranged to connect a positive terminal of a second secondary winding of said at least two secondary windings to the second output terminal connectable to the load, and a fourth secondary switch arranged to connect a negative terminal of the second secondary winding of said at least two secondary windings to a first output terminal connectable to the load.

In one embodiment, the secondary side electric circuitry is arranged to be controlled substantially synchronized with the power provided to the primary winding. This is beneficial as the synchronized operation allows for efficient transfer of energy in the transformer with minimum discrepancy between the primary side switching and the secondary side switching.

In one embodiment, the plurality of secondary switches are controlled at a switching frequency of 30 kHz or higher, preferably 50 kHz or higher, and most preferably 100 kHz or higher. Increased switching frequency allows a size of the transformer be decreased, reducing size and weight of the current booster and increasing portability of the current booster.

In one embodiment, the secondary side electric circuitry is galvanically isolated from said at least two input terminals. This is beneficial as it provides a current booster that is safe to use and that can be reliably and safely connected to a test object.

In one embodiment, a number of turns of each primary winding are at least five times greater than a number of turns of each secondary winding, preferably the number of turns of each primary winding are at least ten times greater than the number of turns of each secondary winding. This is beneficial as the ratio between the windings assist in boosting the current.

In one embodiment, the current booster circuitry further comprises at least one primary side electric circuitry for operatively connecting said at least two input terminals to said at least one primary winding of the transformer, wherein the primary side electric circuitry comprises a plurality of primary switches arranged to control the connection of the power source to the primary winding of the transformer. The primary side electric circuitry is beneficial as it allows a wider range of power sources to be used with the current booster as the primary side electric circuitry may be adapted or controlled depending on the power source.

In one embodiment, the plurality of primary switches are arranged in a half bridge arrangement. This is beneficial as the half bridge is efficient with regards to a number of switches used.

In one embodiment, the plurality of primary switches are arranged in a full bridge arrangement. This is beneficial as the full bridge allows accurate control of the switching of the primary windings.

In one embodiment, said plurality of secondary switches and/or said plurality of primary switches are provided as transistors, preferably FET transistors. This is beneficial as transistors are easily controlled with fast switching times and FET transistors present a comparably low on resistance.

In one embodiment, the transformer comprises a core, preferably a ferrite core. This is beneficial as the core greatly reduce the losses of the coupling between the primary side and the secondary side of the transformer.

In a second aspect, a printed circuit board assembly comprising a multi-layer printed circuit board (PCB) is presented. The PCB comprises a current booster circuitry according to the first aspect and a through hole penetrating all layers of the PCB. Further to this, said at least one primary winding and said at least two secondary windings of the transformer are routed around the through hole.

In one embodiment, at least one of the secondary windings of the transformer of the current booster circuitry is arranged in an internal layer of the PCB. This is beneficial as it increases the coupling between the windings and reduces parasitic effects.

In one embodiment, the transformer of the current booster circuitry comprises one or two primary windings, wherein at least one of said one or two primary windings is arranged in an outer layer of the PCB. This provides efficient routing and floorplan of the PCB.

In a third aspect, a current booster assembly comprising a plurality of printed circuit board assemblies according to the second aspect is presented. In the current booster assembly, said at least two input terminals of the primary windings of the printed circuit board assemblies are connected in series and said at least two output terminals of the printed circuit board assemblies are connected in parallel.

In one embodiment, the through holes of said plurality of printed circuit board assemblies are aligned and a transformer core is arranged though the through holes of said plurality of printed circuit board assemblies. This is beneficial as it allows for a compact design with a several primary windings in series and secondary windings in parallel sharing the same transformer core resulting in a light weight and compact design.

In a fourth aspect, a current booster system is presented. The current booster system comprises one or more current booster assemblies according to the third aspect and a carrier provided with a plurality of sockets. Each printed circuit board assembly, of said one or more current booster assemblies, is arranged in an associated socket of the carrier, and the parallel connection of said at least two output terminals of the printed circuit board assemblies is provided by the carrier.

In one embodiment, the carrier further comprises a primary side electric circuitry operatively connected in parallel across the series connection of the input terminals of the printed circuit board assemblies, of said one or more current booster assemblies. This is beneficial as the primary side electric circuitry may be efficiently shared between a plurality of current booster assemblies.

In one embodiment, the current booster system further comprises a control module for controlling at least the secondary side electric circuitry of the printed circuit board assemblies of said one or more current booster assemblies.

In a fifth aspect, a test equipment for electrical test or measurement comprising one or more current booster circuitry according to the first aspect.

### BRIEF DESCRIPTION OF THE DRAWINGS

Embodiments of the invention will be described in the following; references being made to the appended diagrammatical drawings which illustrate non-limiting examples of how the inventive concept can be reduced into practice.

FIG. 1 is a schematic of a current booster according to prior art;

FIGS. 2a-b are schematics of current boosters according to some embodiments;

FIGS. 3a-b are schematics of current boosters according to some embodiments;

FIG. 4 is a schematic of a current booster according to some embodiments;

FIG. 5 is a time series plot of different signals in a current booster according to some embodiments;

FIG. 6 is schematic view of control logic for a current booster according to some embodiments;

FIG. 7a-c are schematics of primary side electric circuitry according to some embodiment;

FIG. 8 is a schematic of a current booster according to some embodiments;

FIG. 9 is a block diagram of a current booster according to some embodiments;

FIG. 10 is a schematic view of a current booster according to some embodiments;

FIG. 11a-b are views of a printer board assembly according to some embodiments;

FIG. 12 is a perspective view of a current booster assembly according to some embodiments;

FIG. 13 is side view of a current booster system according to some embodiments; and

FIG. 14 is a block diagram of a test equipment according to some embodiments.

### DETAILED DESCRIPTION OF EMBODIMENTS

Hereinafter, certain embodiments will be described more fully with reference to the accompanying drawings. The invention may, however, be embodied in many different forms and should not be construed as limited to the embodiments set forth herein; rather, these embodiments are provided by way of example so that this disclosure will be thorough and complete, and will fully convey the scope of the invention, such as it is defined in the appended claims, to those skilled in the art.

The term “coupled” is defined as connected, although not necessarily directly, and not necessarily mechanically. Two or more items that are “coupled” may be integral with each other. The terms “a” and “an” are defined as one or more unless this disclosure explicitly requires otherwise. The terms “substantially,” “approximately,” and “about” are defined as largely, but not necessarily wholly what is specified, as understood by a person of ordinary skill in the art. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a method that “comprises,” “has,” “includes” or “contains” one or more steps possesses those one or more steps, but is not limited to possessing only those one or more steps.

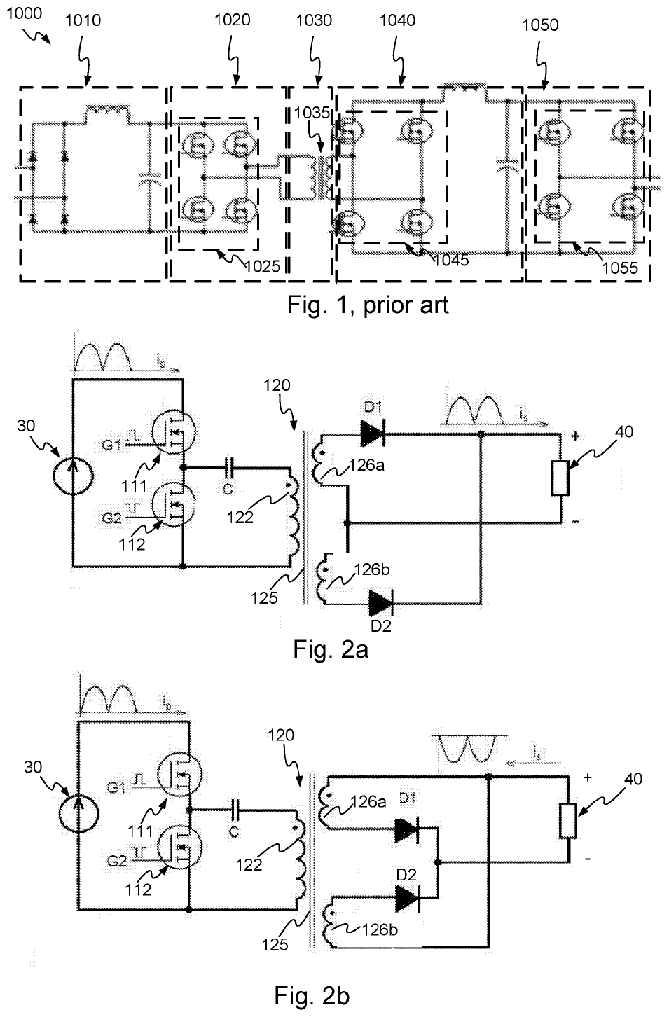

Starting in FIG. 1, a prior art current booster 1000 is presented to give context to the various embodiments of the present invention. The prior art current booster 1000 is generally supplied with an of the grid AC of 50 or 60 Hz depending on regional adaptation, but the skilled person understands that it may be supplied also with a DC if a first stage 1010 of the prior art current booster 1000 is bypassed. Regardless, the first stage 1010 is used when an AC is provided as input power. This AC is supplied to a first stage 1010 of the prior art current booster 1000 at which is rectified before it is provided to a second stage 1020 of the prior art current booster 1000. The second stage 1020 of the prior art current booster 1000 comprises a first plurality of switches 1025, typically arranged as a full bridge to control the rectified current as it is provided to a third stage 1030 of the prior art current booster 1000. The third stage 1030 comprises a transformer 1035, transforming the current provided by the second stage 1020, into a higher current that is provided to a fourth stage 1040 of the prior art current booster 1000. The first plurality of switches 1025 are provided in order to allow the usage of a reduced size transformer 1035 as a switching frequency of the first plurality of switches 1025 may be much higher than the 50 or 60 Hz of the AC grid. A 50 or 60 Hz transformer workable at the currents specified would be unimaginably large and heavy. The fourth stage 1040 comprises a second plurality of switches 1045 arranged to provide a secondary DC that may be provided to a load by a fifth stage 1050 of the prior art current booster 1000. The fifth stage 1050 comprises a third plurality of switches 1055 arranged in a full bridge to control the current to a load. The complexity of the prior art current booster 1000 stems from the requirement to provide a controlled AC or DC current to the load, where the DC current can be provided in two directions through the load. Note that the switches 1045, 1055 of the fourth and fifth stages 1040, 1050 are required to handle the full current through the load putting immense constraints on these components. Even realizing the switches 1045, 1055 on the secondary side by FET transistors will dissipate tremendous amounts of heat in the switches 1045, 1055. Assuming that a transistor capable of handling 10 kA with an R_{ds(on)} of 100 μΩ, would be financially feasible. The dissipated power P in each conducting switch at the secondary side would be P=I²·R_{ds(on)}=(10·10³)²·100·10⁻⁶ W=10 kW. As the device is required to operate in steady state, the specified 10 kA is an RMS value and for three phase AC operations, three current boosters must be added to generate currents in all quadrants, resulting in higher switching and conduction losses. Consequently, the amount of semiconductors increases severely, reducing reliability and efficiency, resulting in high costs and complexity.

With reference to FIGS. 2a and 2b, the conceptual idea of this disclosure will be explained in more detail. In FIGS. 2a-b, a positive output converter is illustrated. The converter receives power from a power source 30 in the form of a current source 30. The current source 30 provides, for illustrative purposes, a primary side current iₚ as a full wave rectified sinusoidal current. The primary side current iₚ is provided to a primary winding 122 of a transformer 120 via two primary side transistors 111, 112 connected in a half bridge. The primary side transistors 111, 112 are controlled by a respective first and second control signal G1, G2. The first and second control signals G1, G2 are preferably phase shifted 180° with regards to each other such that if one of them is active, the other one is inactive. The secondary side of the transformer 120 is provided with a first secondary winding 126a and a second secondary winding 126b. As seen in FIGS. 2a-b, a marking is visible at each of the windings 122, 126a, 126b. This marking is, as is known to the skilled person, a polarity marking and will be used throughout this disclosure to indicate a positive terminal of a transformer winding. The secondary windings 126a, 126b are connected in series, such that a negative terminal of the first secondary winding 126a is connected to a positive terminal of the second secondary winding 126b.

When the first control signal G1 is such that a first primary side transistor 111 is short-circuited, the second control signal G2 is preferably such that a second primary side transistor 112 is not conducting. When the first primary side transistor 111 is conducting, current will flow into the positive terminal of the primary winding 122 and consequently out from the positive terminals of the secondary windings 126a, 126b. As G1 and G2 substantially are inverses to each other, when first primary side transistor 111 is not conducting, the second primary side transistor 112 is short-circuited allowing current to flow in the out from the positive terminal of the primary winding 122. As current is controlled to flow out of the positive terminal on the primary winding 122, current will flow into the positive terminals of the secondary windings 126a, 126b. For simplicity, it is assumed that the primary side control signals G1, G2 are fast enough to switch the primary side transistors 111, 112 sufficiently fast to provide a substantially ripple free secondary side current iₛ to the load 40.

In the illustrative example of FIG. 2a, a first diode D1 is arranged in series with a positive terminal of the first primary winding 126a and a positive terminal of a load 40 with its anode facing the positive terminal of the first primary winding 126a. A second diode D2 is arranged in series with a negative terminal of the second secondary winding 126b and the positive terminal of the load 40 with its anode facing the negative terminal of the second secondary winding 126b. The negative side of the load 40 is connected to the negative terminal of the first secondary winding 126a and the positive terminal of the second secondary winding 126b. This effectively connects the load 40 in parallel with secondary windings 126a, 126b that are phase shifted, or mirrored with regards to the load 40. As the primary side current iₚ is full wave rectified, current will flow from the positive terminal of the primary winding 122 when the first primary transistor 111 is short-circuited and into the positive terminal of second secondary winding 126b when the second primary transistor is conducting, i.e. short-circuited. On the secondary side, if there would have been no diodes D1, D2, no current would be provided to the load 40 as the secondary windings 126a, 126b are connected in series, and the positive terminal of the first secondary winding 126a would be short-circuited to the negative terminal of the second secondary winding 126b. However, as the second diode D2 is arranged with its anode towards the negative terminal of the second secondary winding 126b, this stops any current from flowing through the second secondary winding 126b in a direction out from the positive terminal of the second secondary winding 126b. However, as the first diode D1 is arranged with its anode towards the positive terminal of the first secondary winding 126a, current may flow through the first secondary winding 126a in a direction out from the positive terminal of the first secondary winding 126a. In other words, in the scenario of FIG. 2a, on the secondary side of the transformer 120, current will either be permitted to flow out from the positive terminal of the first secondary winding 126a or into the positive terminal of the second secondary winding 136b. As previously explained, if the secondary current iₛ is provided from the first secondary winding 126a or the second secondary winding 126b will be decided depending on the direction of the current into the primary winding 122, i.e which of the first or second primary transistors 111, 112 that is currently conducting. Consequently, the secondary current iₛ will, with regards to the polarity of the load 40, be positive and provided from the first secondary winding 126a. As the primary side current iₚ is full wave rectified and the switching frequency was sufficiently high, also the secondary current iₛ will be a smooth full wave rectified current.

Turning now to FIG. 2b. The example illustrated in FIG. 2b is identical to that of FIG. 2a with exception of the placement of the diodes D1, D2 on the secondary side of the transformer 120. In FIG. 2b, the placement of the diodes D1, D2 has shifted such that the first diode D1 is arranged in series with the negative terminal of the first primary winding 126a and the negative terminal of a load 40 with its anode facing the negative terminal of the first primary winding 126a. The second diode D2 is arranged in series with the positive terminal of the second secondary winding 126b and the negative terminal of the load 40 with its anode facing the positive terminal of the second primary winding 126b. As nothing else has changed, and as the primary current iₚ still is a positive full wave rectified current, the first diode D1 stop current from flowing out from the positive terminal of the first secondary winding 126a, but permit current from flowing into the positive terminal of the first secondary winding 126a. However, as current is now permitted to flow out from the positive terminal of the second secondary winding 126b, through the second diode D2 and into the negative terminal of load 40, a direction of the secondary current is, with regards to the load 40, has changed compared to the example of FIG. 2a.

The diodes D1, D2 of FIGS. 2a-b have an inherent forward voltage drop that will cause losses on the secondary side of the transformer 120. In order to reduce these losses, switches having lower insertion loss may be introduced.

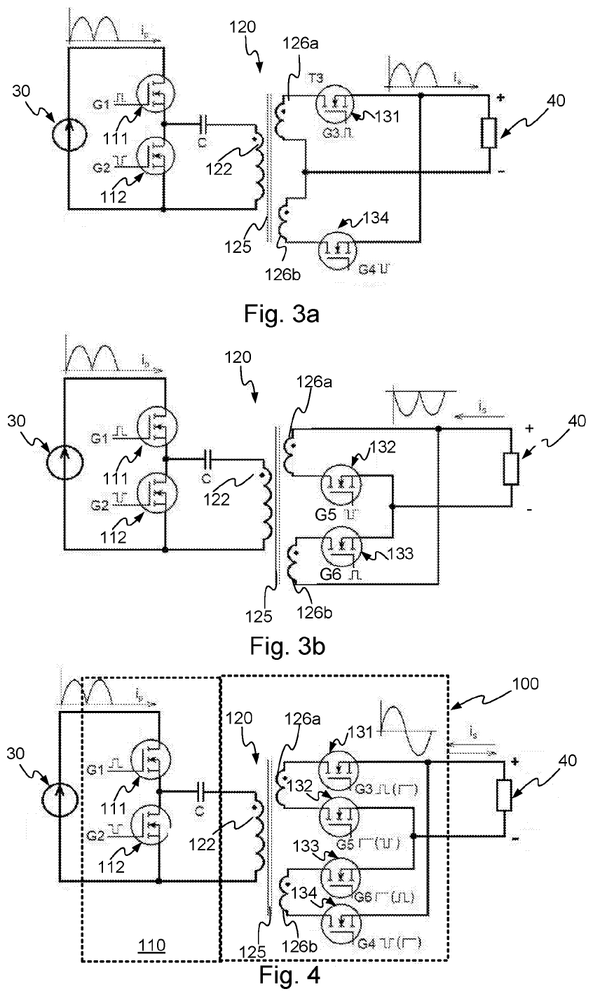

In FIG. 3a, the corresponding schematic as in FIG. 2a is shown, but with the first diode D1 of FIG. 2a replaced with a first secondary switch 131 in FIG. 3a and the second diode D2 of FIG. 2a is replaced with a fourth secondary switch 134 in FIG. 3a. The first and fourth secondary switches 131, 134 in FIG. 3a are illustrated as FET transistors but any suitable switch may be utilized such as IGBT transistors, BJTs etc. The skilled person will understand that increased on-resistance of the respective switch will reduce efficiency of a booster and preferably a switching technology with as low insertion loss as possible is chosen The first secondary switch 131 in FIG. 3a is controlled by a third control signal G3 and the fourth secondary switch 134 is controlled by a fourth control signal G4. From the description given with reference to FIG. 2a, it is understood that the first secondary switch 131 and the fourth secondary switch 134 are preferably controlled by mutually inverted control signals G3, G4 similar to that of the first and second control signals G1, G2 as previously specified. That is to say, the third and fourth control signals G3, G4 are preferably phase shifted 180° with regards to each other such that if one of them is active, the other one is inactive. Preferably, the third control signal G3 is controlled in a substantially synchronized manner to the first control signal G1 such that the first primary switch 111 and the first secondary switch 131 are short-circuited at the same time, i.e. allowing current to flow into the positive terminal of the primary winding 122 and out from the positive terminal of the first secondary winding 126a. Correspondingly, the fourth control signal G4 is controlled in a substantially synchronized manner to the second control signal G2 such that the second primary switch 112 and the fourth secondary switch 134 are short-circuited at the same time, i.e. allowing current to flow out from the positive terminal of the primary winding 122 and into from the positive terminal of the second secondary winding 126a. The synchronized control is beneficial as each switch has an inherent switching time at which it has high insertion loss and is consequently dissipating power during the switching. As comparably little power is transferred during the switching of the primary side, it is beneficial to synchronously switch at the secondary side in order to minimize switching losses and maximize booster efficiency.

Accordingly, FIG. 3b is corresponding to FIG. 2b but in FIG. 3b. But, corresponding to the differences between FIGS. 2a and 3a, the first diode D1 of FIG. 2b is replaced with a second secondary switch 132 in FIG. 3b and the second diode D2 of FIG. 2b is replaced with a third secondary switch 133 in FIG. 3b. The second and third secondary switches 132, 133 in FIG. 3b are illustrated as FET transistors but any suitable switch may be utilized such as IGBT transistors, relays etc. The second secondary switch 132 in FIG. 3b is controlled by a fifth control signal G5 and the third secondary switch 133 is controlled by a sixth control signal G6. From the description given with reference to FIG. 2b, it is understood that the second secondary switch 132 and the third secondary switch 133 are preferably controlled by mutually inverted control signals G5, G6. That is to say, the fifth and sixth control signals G5, G6 are preferably phase shifted 180° with regards to each other such that if one of them is active, the other one is inactive. Preferably, the fifth control signal G5 is controlled in a substantially synchronized manner to the second control signal G2 such that the second primary switch 112 and the second secondary switch 132 are short-circuited at the same time, i.e. allowing current to flow out from the positive terminal of the primary winding 122 and into the positive terminal of the first secondary winding 126a. Correspondingly, the sixth control signal G6 is controlled in a substantially synchronized manner to the first control signal G1 such that the first primary switch 111 and the third secondary switch 133 are short-circuited at the same time, i.e. allowing current to flow into the positive terminal of the primary winding 122 and out from the positive terminal of the second secondary winding 126b.

From the description given with reference to the FIGS. 2a-b and 3a-b, the skilled person will understand that the embodiments of FIGS. 3a-3b may be combined into one circuit; such an embodiment of a current booster 100 is illustrated in FIG. 4. In FIG. 4, the secondary side of the transformer 120 comprises the first through fourth secondary switches 131, 132, 133, 134 and the primary side of the transformer 120 is identical to that of FIGS. 2a-b and 3a-b. The first secondary switch 131 is connected to control a connection between the positive terminal of the first secondary winding 126a and the positive terminal of the load 40. The first secondary switch 131 is controlled by the third control signal G3, preferably synchronous with the first control signal G1. The second secondary switch 132 is connected to control a connection between the negative terminal of the first secondary winding 126a and the negative terminal of the load 40. The second secondary switch 132 is controlled by the fifth control signal G5, preferably synchronous with the second control signal G2. The third secondary switch 133 is connected to control a connection between the positive terminal of the second secondary winding 126b and the negative terminal of the load 40. The third secondary switch 133 is controlled by the sixth control signal G6, preferably synchronous with the first control signal G1. The fourth secondary switch 134 is connected to control a connection between the negative terminal of the second secondary winding 126b and the positive terminal of the load 40. The fourth secondary switch 134 is controlled by the fourth control signal G4, preferably synchronous with the first control signal G2. With the circuitry as embodied in FIG. 4, it is possible to provide a secondary current iₛ into either the positive or negative terminal of the load 40. That is to say, the direction of secondary current iₛ through the load 40 is controllable regardless of a polarity of the primary current iₚ provided by the power source 30.

With continued reference to FIG. 4, if it is assumed that the primary side current iₚ as a full wave rectified sinusoidal current as illustrated in FIG. 4, an unrectified zero offset sinusoidal current may be provided to the load 40.

The positive half period of the secondary current iₛ may be provided by, for a first half period of the primary side current iₚ, allowing the circuitry of FIG. 4 to operate as the circuitry presented in FIG. 3a. This may be achieved by having the first secondary switch 131 and the second secondary switch 132 short-circuited simultaneously as the first primary switch 111 is short-circuited and the third secondary switch 133 and the fourth secondary switch 134 short-circuited simultaneously as the second primary switch 112 is short-circuited. Consequently, at least one of the third secondary switch 133 and the fourth secondary switch 134 is non-conducting when the first primary switch is conducting, and at least one of the first secondary switch 131 and the second secondary switch is non-conductive when the second primary switch 112 is active, i.e. conducting. This control scheme will allow the circuit of FIG. 4 to operate analogously to the circuit in FIG. 3a providing a positive secondary current iₛ to the load 40, i.e. a secondary current iₛ flowing into the positive terminal of the load 40. This scenario will be referred to a positive current scenario.

The negative half period of the secondary current iₛ may be provided by, for a second half period of the primary side current iₚ, allowing the circuitry of FIG. 4 to operate as the circuitry presented in FIG. 3b. This may be achieved by having the first secondary switch 131 and the second secondary switch 132 short-circuited simultaneously as the second primary switch 112 is short-circuited and the third secondary switch 133 and the fourth secondary switch 134 short-circuited simultaneously as the first primary switch 111 is short-circuited. Consequently, at least one of the third secondary switch 133 and the fourth secondary switch 134 is non-conducting when the second primary switch 112 is conducting and at least one of the first secondary switch 131 and the second secondary switch 132 is non-conductive when the first primary switch 111 is active, i.e. conducting. This control scheme will allow the circuit of FIG. 4 to operate analogously to the circuit in FIG. 3b providing a negative secondary current iₛ to the load 40, i.e. a secondary current iₛ flowing out from the positive terminal of the load 40. This scenario will be referred to a negative current scenario.

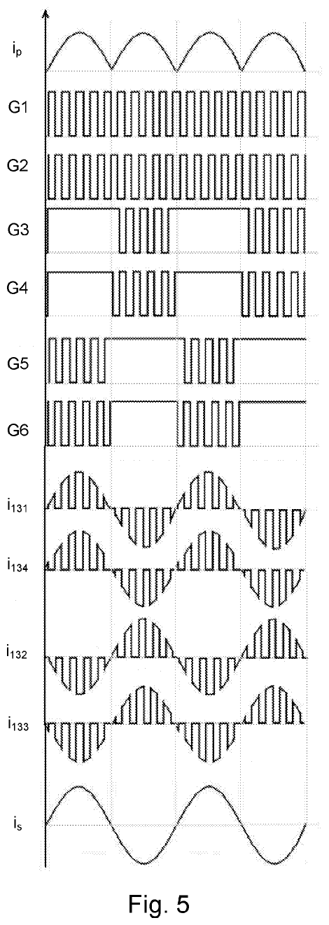

In order to reduce e.g. switching losses and control logic complexity, a control scheme as illustrate in FIG. 5 may be utilized. In FIG. 5, all signals are illustrates along a common time x-axis. FIG. 5 shows the time plot of the control signals G1-G6 aligned with corresponding primary current iₚ, secondary current iₛ, a first secondary switch current i₁₃₁ flowing through the first primary switch 131, a second secondary switch current i₁₃₂ flowing through the second secondary switch 132, a third secondary switch current i₁₃₃ flowing through the third secondary switch 133 and a fourth secondary switch current i₁₃₄ flowing through the fourth secondary switch 132. Positive current scenarios are during first and third half-periods of the primary current iₚ, and negative current scenarios are during second and fourth half-periods of the primary current iₚ.

In the scheme of FIG. 5, during the positive current scenarios, the first secondary switch 131, controlled by the third control signal G3, being in synch with the first primary switch 111, controlled by the first control signal G1, and the second secondary switch 132, controlled by the fifth control signal G5, is constantly active, i.e. short-circuited or conducting. Further to this, during the positive current scenario, the fourth secondary switch 134, controlled by the fourth control signal G4, is in synch with the second primary switch 112, controlled by the second control signal G2, and the third secondary switch 132, controlled by the sixth control signal G6, is constantly active, i.e. short-circuited or conducting.

Staying with FIG. 5 but focusing on the negative current scenarios, the first secondary switch 131, controlled by the third control signal G3, being in synch with the first primary switch 111, controlled by the first control signal G1, and the second secondary switch 132, controlled by the fifth control signal G5, is constantly active, i.e. short-circuited or conducting. Further to this, during the positive current scenario, the fourth secondary switch 134, controlled by the fourth control signal G4, is in synch with the second primary switch 112, controlled by the second control signal G2, and the third secondary switch 132, controlled by the sixth control signal G6, is constantly active, i.e. short-circuited or conducting.

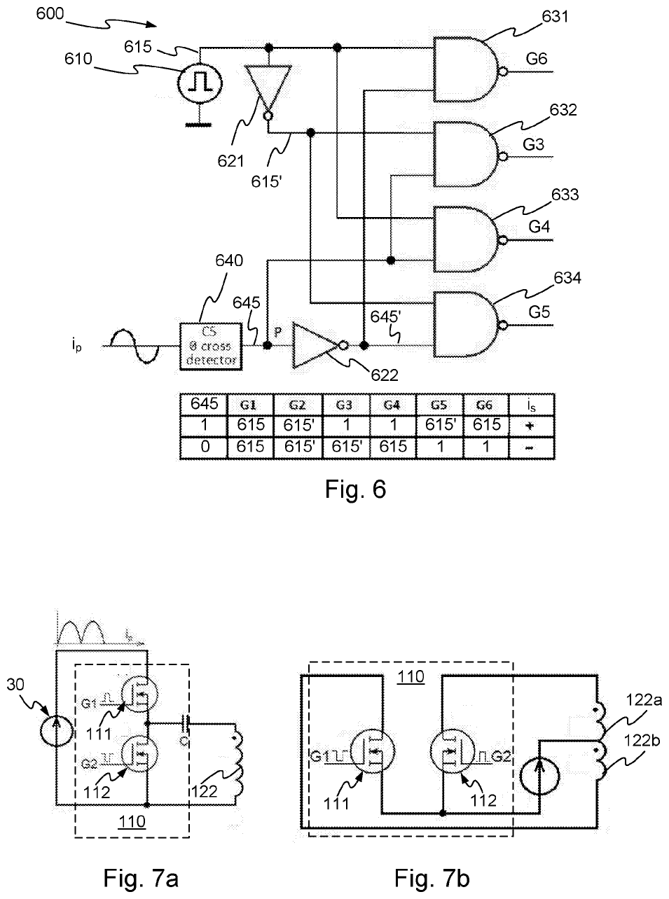

The control of the current booster 100 of FIG. 4 may be provided in numerous ways through software and/or hardware. With reference to FIG. 6, a control logic 600 for providing the control scheme of FIG. 5 will be presented. In FIG. 6 a logic diagram is illustrated together with the control logic 600. In the logic diagram, the scenarios of the secondary current iₛ are indicated with a “+” for the positive current scenario and a “−” for the negative current scenario. The control logic 600 comprises a pulse generator 610 configured to generate a pulsed signal 615 at a comparably high switching frequency f_{sw}. The switching frequency f_{sw} is generally above 30 kHz, but is preferably above 50 kHz and most preferably above 100 kHz. The high switching frequency f_{sw} is beneficial as it enables the transformer 120 to be comparably small and light weight compared to if a lower switching frequency f_{sw} is used. The first control signal G1 is synchronized and in phase with the pulsed signal 615, and the second control signal G2 is the inverse, i.e. phase shifted 180°, with regards to the pulsed signal 615. The control logic 600 further comprise a phase cross detector 640 arranged to provide a phase signal 645 indicating a positive or negative phase of the primary current iₚ. In this scenario, if the phase of the primary current iₚ is positive, the phase signal 645 is high, and if the phase primary current iₚ is negative, the phase signal is low. The control logic 600 further comprises a first inverter 621 arranged to provide an inverted pulsed signal 615′ and a second inverter 622 arranged to provide an inverted phase signal 645′. The sixth control signal G6 is provided by a first NAND gate 631 arranged to provide a logic NAND of the pulsed signal 615 and the inverted phase signal 645′. The third control signal G3 is provided by a second NAND gate 632 arranged to provide a logic NAND of the inverted pulsed signal 615′ and the phase signal 645. The fourth control signal G4 is provided by a third NAND gate 633 arranged to provide a logic NAND of the pulsed signal 615 and the phase signal 645. The fifth control signal G5 is provided by a fourth NAND gate 634 arranged to provide a logic NAND of the inverted pulsed signal 615′ and the inverted phase signal 645′.

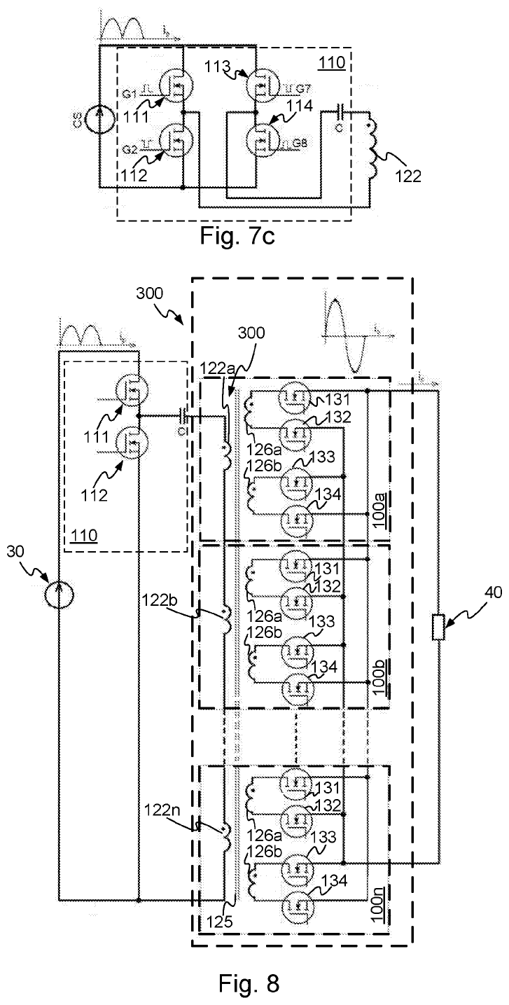

As is understood from this disclosure, one great part if the inventive concept lies in having the secondary windings 126a, 126b of a transformer 120 connected in parallel via secondary switches 131, 132, 133, 134 and phase shifted across a load 40. This enables providing a current through the load in both positive and negative direction together with allowing an increased switching frequency of several kHz reducing the size of the transformer. However, for the sake of completeness, some different circuitry for connecting the power source 30 the primary winding 122 will be presented with reference to FIGS. 7a-c. The circuitry operatively connecting the power source 30 to the primary winding 122 of the transformer 120 will be referred to as a primary side electric circuitry 110.

In the embodiment of FIG. 7a, the primary side electric circuitry 110 comprises the first primary switch 111 and the second primary switch 112 arranged in a half bridge formation. In order not to saturate the transformer, a capacitor C may be arranged in series with the primary winding 122.

Turning to FIG. 7b, a primary side electric circuitry 110 comprising the first primary transistor 111 and the second primary transistor 112 arranged in a push-pull arrangement is presented. In this embodiment, the primary winding 122 comprises a first primary winding 122a and a second primary winding 122b. The push pull arrangement is provided to control the current either through the first primary winding 122a or the second primary winding 122b.

In FIG. 7c, the primary side circuitry is provided in the form of a full bridge arrangement with the first primary switch 111 and the second primary switch 112 arranged to form a first leg of the full bridge and a third primary switch 113 and a fourth primary switch 114 arranged to form a second leg of the full bridge. The third primary switch 113 is controlled by a seventh control signal G7 that may be the second control signal G2 and the fourth secondary switch 114 is controlled by an eighth control signal G8 that may be the first control signal G1.

In some embodiments, the power source 30 may comprise the primary side electric circuitry 110.

With reference to FIG. 8, one embodiment of a current booster assembly 300 will be presented. The current booster assembly 300 of FIG. 8 comprises a plurality of current boosters 100a, 100b, . . . , 100n connected in parallel across the load 40. This enables the secondary current iₛ to be divided amongst the current boosters 100a, 100b, . . . 100n making it possible to add any number of current boosters 100a, 100b, . . . , 100n in parallel in order to create secondary currents is of well above 1 kA. In the embodiment of FIG. 8, the transformer 120 comprises a plurality of primary windings 122a, 122b, . . . , 122n and each of the current boosters 100a, 100b, . . . , 100n is connected to separate first and second secondary windings 126a, 126b. This is but one example, embodiments with only one primary winding 122 or any other number of secondary windings 126a, 126b are, as the skilled person will appreciate after digesting the teaching herein, well within the scope of the present disclosure. The primary windings 122a, 122b, . . . , 122n of the transformer 120 of the current booster assembly 300 are arranged in series and connected to the power source 30 through a primary side electric circuitry 110 in the form of a half bridge. Any other suitable topologies of the primary circuit are possible and one or more of the primary windings 122a, 122b, . . . , 122n may in some embodiments be connected in parallel to the power source 30. The current booster assembly 300 may have each of the current boosters 100a, 100b, . . . , 100n activated and e.g. controlled as previously described, or only a number of the current boosters 100a, 100b, . . . , 100n may be active. By controlling the number of active current boosters 100a, 100b, . . . , 100n, an amplitude of the secondary current iₛ may be controlled.

The current booster assembly 300 of FIG. 8 is illustrated with current boosters 100a, 100b, . . . , 100n similar to the current booster 100 presented in FIG. 4. However, for the sake of completeness, the skilled person will appreciate that a current booster 100 may very well be formed by connecting the circuitry of FIGS. 2a and 2b in parallel to the load 40 and activating only one of the circuitry depending e.g. the wanted polarity, i.e. phase, of the secondary current is. Such control may be provided by e.g. relays, switches or transistors. The same reasoning is applicable to the combination of the embodiments in FIGS. 3a and 3b, but in this embodiment no additional switches are required. In summary, also the circuitry connecting the secondary windings 126a, 126b to the load may be formed in a number of different ways and all are to be considered covered by the present disclosure.

In FIG. 8, the transformer 120 comprises a core 125 that significantly increases the coupling from the primary windings 122a, 122b, . . . , 122n to the secondary windings 126a, 126b. Albeit most of the embodiments of the transformer 120 of the present disclosure are illustrated with a core 125, it should be mentioned that the transformer core 125 is not essential to the invention.

In a preferred embodiment of the current booster 100, not necessarily the current booster 100 of FIG. 8, the core 125 of the transformer 120 is a ferrite core. This increases coupling but reduces core losses that occur at high switching frequencies if e.g. an iron core is used.

It should be mentioned that the current booster assembly 300 may also be formed by the current booster 100 as illustrated in FIG. 4. In such an embodiment, each current booster 100 may comprise the primary side electric circuitry 110, and a plurality of these current boosters 100 may be connected in parallel across the load 40 to provide a boosted secondary current iₛ of tens of kA.

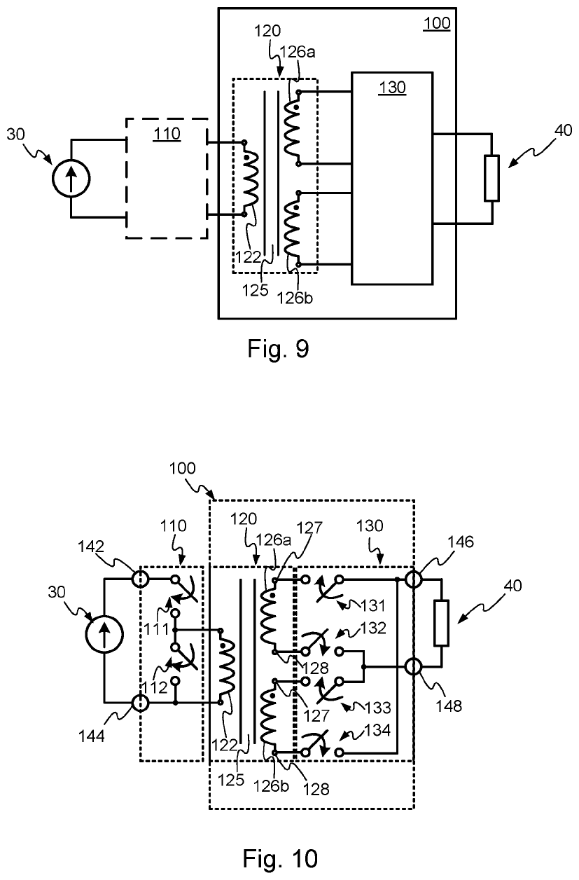

A large number of different embodiments of current boosters 100 have been presented, and these may be summarized in the current booster 100 schematically illustrated in FIG. 9. In this embodiment, the current booster comprises a transformer 120 having at least one primary winding 122. As previously presented, there may be any number of primary windings 122. The transformer 120 further comprises at least two secondary windings 126a, 126b and may optionally comprise a core 125. The primary winding 122 are adapted to be connected to a power source 30, preferably a current source 30. Depending on what circuitry is included in the current source 30, it may be directly connected to the primary winding 122 of the transformer 120. Preferably, the power source 30 is connected to the primary winding 122 via the primary side electric circuitry 110. The primary side electric circuitry 110 may be comprised in the current booster 100 or external to the current booster 100 depending on e.g. system requirements and formed in any suitable way, not limited to the examples presented herein. The first and second secondary windings 126a, 126b of the transformer are arranged to be connected to the load 40 via a secondary side electric circuitry 130. The secondary side electric circuitry 130 may be embodied in any suitable way with any number of diodes, switches or transistors as described herein. The important thing is that the secondary side electric circuitry 130 is arranged to connect the secondary windings 126a, 126b to the load with respective polarities of the secondary windings 126a, 126b mutually reversed. That is to say, the secondary electric circuitry 130 is arranged to connect the positive terminal of the first secondary winding 126a and the negative terminal of the second secondary winding 126b to the same terminal of the load 40, be it the positive or negative terminal of the load 40 or a connection terminal for the load 30 comprised in, or external to, the current booster 100. The secondary electric circuitry 130 is further arranged to connect the negative terminal of the first secondary winding 126a and the positive terminal of the second secondary winding 126b to the same terminal of the load 40, being the other terminal of the load 40 than the one mentioned above.

Turning to FIG. 10 a preferred embodiment of the current booster 100 is illustrated. This embodiment of the current booster 100 is autonomous and may be connected directly between the power source 30 and the load 40. The current booster comprises at least two input terminals 142, 144 for connecting to the power source 30, at least a first output terminal 146 and a second output terminal 148 for connecting to the load 40, at least one transformer 120 provided with at least one primary winding 110 and at least a first secondary windings 126a and a second secondary winding 126b, at least one primary side electric circuitry 110 operatively connecting said at least two input terminals 142, 144 to said at least one primary winding 122, and at least one secondary side electric circuitry 130 operatively connecting said at least two output terminals 146, 148 to said at least two secondary windings 126a, 126b. Wherein the secondary side electric circuitry 130 is arranged such that a positive terminal 127 of the first secondary winding 126a is connected via a first secondary switch 131 to the first output terminal 146, a negative terminal 128 of the first secondary winding 126a is connected via a second secondary switch 132 to the second output terminal 148, a positive terminal 127 of the second secondary winding 126b is connected via a third secondary switch 133 to the first output terminal 146, and a negative terminal 128 of the second secondary winding 126b is connected via a fourth secondary switch 134 to the second output terminal 148.

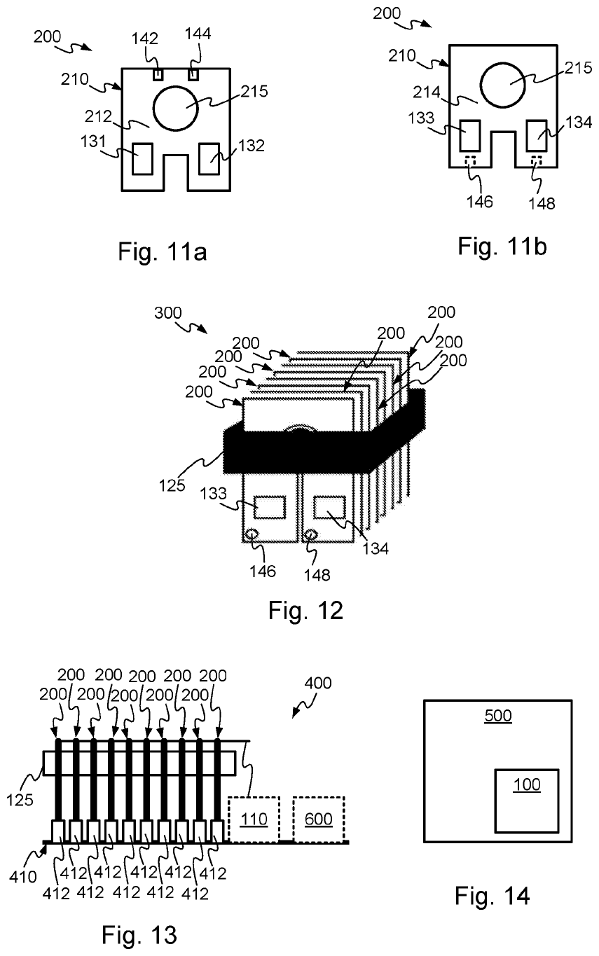

As previously presented, a plurality of the disclosed current booster 100 may be connected in parallel in order to further increase the secondary current is. In order to do so efficiently, the inventor behind this disclosure has realized that the design of the current booster 100 may be efficiently provided on a printed board assembly 200, see FIGS. 11a and 11b. The printed board assembly 200 comprises a printed circuit board, PCB, 210 for mounting components and providing routing for a selected embodiment of the secondary side electric circuitry 130. The primary winding 122 and the secondary windings 126a, 126b of the transformer are formed by loops in the PCB 110. The primary winding 122 is preferably arranged in one or more layers of the PCB that are different from one or more layers of the PCB in which that secondary windings 126a, 126b are routed. The inventor has further realized that by providing the PCB 210 with a through hole 215 and routing the primary winding 122 and the secondary windings 126a, 126b around the hole, as will be detailed elsewhere, stacking of the printed board assembly 200 can be made much more efficient. If the PCB 210 is a dual layer PCB, primary windings 122 are arranged at a first side 212, FIG. 11a, of the PCB 210 and the secondary windings 126a, 126b are arranged at a second side, FIG. 11b, of the PCB 214. Depending on the embodiment of the secondary side electric circuitry 130, the secondary switches 131, 132, 133, 134 may be arranged either on one or both sides 212, 214 of the PCB 210. The PCB 210 may further comprise input terminals 142, 144 operatively connected to the primary winding 122. The input terminals 142, 144 are preferably arranged at a common edge of the PCB 210 in order to simplify the connection of primary windings 122 of two or more printed board assemblies 200 in series or parallel, e.g. as illustrated in FIG. 8. The PCB 210 may further comprise output terminals 146, 148 operatively connected to the secondary windings 126a, 126b via the secondary side electric circuitry 130. The output terminals 146, 148 are preferably arranged at a common edge of the PCB 210 in order to simplify the connection of secondary windings 122 of two or more printed board assemblies 200 in parallel, e.g. as illustrated in FIG. 8.

In one embodiment of the printed board assembly 200, the PCB 210 is formed with more than two layers and in this embodiment, the secondary windings 126a, 126b are preferably arranged in inner layers of the PCB 210. If the current booster 100 is provided with two primary windings 122a, 122b, they are preferably arranged one in each of the two outer layers of the PCB 210. This provides efficient routing and good galvanic isolation between the primary side and the secondary side. Further to this, parasitic effects are reduced and the efficiency of the current booster 100 is increased.

With reference FIG. 12, a current booster assembly 300 according to one embodiment will be explained. The current booster assembly 300 of FIG. 12 may be the current booster assembly 300 as illustrated in FIG. 8. The current booster assembly 300 of FIG. 12 is formed from a at least two printed board assemblies 200 as previously presented. By connecting input terminals 142, 144 of each of the printed board assemblies 200 in series and the output terminals 146, 148 of the printed board assemblies in parallel, a current booster assembly 300 capable of delivering very high currents is provided.

In a preferred embodiment of the current booster assembly 300, the through holes 215 of the printed board assemblies 200 are aligned and a common transformer core 125 is arranged through the holes 215 of the printed board assemblies 200. In FIG. 13, a current booster system 400 is presented. The current booster system 400 comprises one or more of the current booster assemblies 200 as described with reference to FIG. 12. The current booster system 400 further comprises a carrier 410 provided with a plurality of sockets 412. The sockets 412 are preferably arranged spaced apart and aligned such that each socket 412 may receive part of a current booster assembly 200. Preferably, each current booster assembly 200 of the current booster system 400 is received by two sockets 412 of the carrier 410, one operatively connecting the first output terminal 146 of the current booster assembly 200 to the carrier 410 and the other operatively connecting the second output terminal 148 of the current booster assembly 200 to the carrier 410. The carrier 410 may be provided with e.g. routing arranged to operatively connect the output terminals 146, 148 of the current booster assemblies 200 in parallel. The carrier 410 may further be provided with load terminals (not shown) for operatively connecting the parallel output terminals 146, 148 of the current booster assemblies 200 to the load 40.

In one embodiment of the current booster assembly 300, the input terminals 142, 144 of the current booster assemblies 200 are connected in series, and the carrier 410 is further provided with the primary side electric circuitry 110 operatively connected in parallel across the series connection of the input terminals 142, 144 of the current booster assemblies 200.

In a further embodiment, the current booster system 400 comprises a control module 600 for controlling at least the secondary side electric circuitry 130 of the printed circuit board assemblies 200. In one embodiment the control module 600 is arranged to also control the primary side electric circuitry 110. In an even further embodiment, the control module 600 is the control logic 600 as explained with reference to FIG. 6.

FIG. 14 is schematic view of an equipment 500 comprising at least one current booster 100 according to any of examples given within this disclosure. The equipment 500 may be any kind of equipment where current conversion is required or desired. Preferably the equipment 500 is an equipment 500 for test or measurement. The equipment 500 may be used for testing or measurement of e.g. trip levels in protection relays and/or motor switch relays. Further to this, the teachings of the present disclosure are usable also when e.g. measuring transformer ratio of a Current Transformer, measuring contact resistance of High Voltage circuit breakers. Additionally, the teachings are applicable for use as a microohmmeter or for fast charging of a ultracapacitor etc.

Although not explicitly detailed, the load 40 is preferably in galvanic isolation from the power source 30. The transformer 120 provides a galvanic isolation, but as the skilled person understands, isolating the primary side galvanically from the secondary since may entail introducing galvanic isolation also on some or all control signals G1-G8. This may be provided by e.g. optical couplers, capacitive couplers, signal transformers, etc., all of which are known to the skilled person. This is beneficial as it provides a current booster that is safe to use and that can be reliably and safely connected to a test object.

Further to this, the skilled person will, after reading this disclosure, understand that a number of turns N_{P1} of each primary winding 122 are preferably greater than a number of turns N_{S1}, N_{S2} of each secondary winding 126a, 126b. In one embodiment, the number of turns N_{P1} of each primary winding 122 are at least five times greater than a number of turns N_{S1}, N_{S2} of each secondary winding 126a, 126b. In a further embodiment, the number of turns N_{P1} of each primary winding 122 are at least ten times greater than the number of turns N_{S1}, N_{S2} of each secondary winding 126a, 126b. This is beneficial as the ratio between the windings assist in boosting the current, the greater the difference, the greater the boosted current.

It should be noted that the power source 30 is illustrated as providing a full wave rectified sinusoidal current in most embodiment of this disclosure. As the skilled person understands, this is for illustrative explanatory purposes only. The power source 30 may, as indicated, be any suitable source of power, both in the form of current and voltage. The power may be provided in any shape of AC or as a DC in either a positive or negative direction.

Further to this, it should be mentioned that the secondary current iₚ, albeit illustrated as an AC coupled sinusoidal wave, may be controlled to an AC of any desired shape, or as a DC in either a positive or negative direction.

The current booster 100 of the present invention has been presented in several working embodiments. Many of these embodiments may be combined to form alternative, not explicitly disclosed embodiments, of the current booster 100. Also such combination are to be considered fully disclosed and covered by the present disclosure. The same applies to e.g. the presented printed board assemblies 200, current booster assemblies 300, current booster systems 400 and equipment 500 in which different embodiment of the current boosters 100 may be combined in any suitable way to achieve a desired effect. As an example, although a current booster 100 is presented and explained, the skilled will have understood, after reading this disclosure, that also a voltage booster may be provided from the same circuitry as the current booster 100. The circuitry of the current booster 100 is commutative, and by changing positions of the power source 30 and the load 40, a voltage booster may be provided. The voltage boosting embodiment is applicable also for the printed board assembly 200, the current booster assembly 300, the current booster system 400 and the test equipment 500.

1. A current booster circuitry (100) for providing a boosted current from a power source (30) to a load (40), the current booster circuitry (100) comprising:
a transformer (120);
at least two input terminals (142, 144) for operatively connecting the power source (30) to at least one primary winding (122) of the transformer (120);
at least two output terminals (146, 148) for operatively connecting the load (40) in parallel to at least two secondary windings (126a, 126b) of the transformer (120); and
a secondary side electric circuitry (130) comprising a plurality of secondary switches (131, 132, 133, 134) arranged for controlling a direction of the boosted current and arranged to connect the secondary windings (126a, 126b) to at least two output terminals (146, 148) with respective polarities of the secondary windings (126a, 126b) mutually reversed, wherein said plurality of secondary switches (131, 132, 133, 134) comprises at least:
a first secondary switch (131) arranged to connect a positive terminal (127) of a first secondary winding (126a) of said at least two secondary windings (126a, 126b) to a first output terminal (146) connectable to the load (40),
a second secondary switch (132) arranged to connect a negative terminal (128) of the first secondary winding (126a) of said at least two secondary windings (126a, 126b) to a second output terminal (148) connectable to the load (40),
a third secondary switch (133) arranged to connect a positive terminal (127) of a second secondary winding (12b) of said at least two secondary windings (126a, 126b) to the second output terminal (148) connectable to the load (40), and
a fourth secondary switch (134) arranged to connect a negative terminal (128) of the second secondary winding (126b) of said at least two secondary windings (126a, 126b) to a first output terminal (146) connectable to the load (40).

2. The current booster circuitry (100) of claim 1, wherein the secondary side electric circuitry (130) is arranged to be controlled substantially synchronized with the power provided to the primary winding (122).

3. The current booster circuitry (100) of claim 1, wherein said plurality of secondary switches (131, 132, 133, 134) are controlled at a switching frequency of 10 kHz or higher, preferably 50 kHz or higher, and most preferably 100 kHz or higher.

4. The current booster circuitry (100) of claim 1, wherein the secondary side electric circuitry (130) is galvanically isolated from said at least two input terminals (142, 144).

5. The current booster circuitry (100) of claim 1, wherein a number of turns (NP1) of each primary winding (122) are at least five times greater than a number of turns (Ns1, Ns2) of each secondary winding (126a, 126b), preferably the number of turns (NP1) of each primary winding (122) are at least ten times greater than the number of turns (Ns1, Ns2) of each secondary winding (126a, 126b).

6. The current booster circuitry (100) of claim 1, further comprising at least one primary side electric circuitry (110) for operatively connecting said at least two input terminals (142, 144) to said at least one primary winding (122) of the transformer (120), wherein the primary side electric circuitry (110) comprises a plurality of primary switches (111, 112) arranged to control the connection of the power source (30) to the primary winding (122) of the transformer (120).

7. The current booster circuitry (100) of claim 6, wherein the plurality of primary switches (111, 112) are arranged in a half bridge arrangement.

8. The current booster circuitry (100) of claim 6, wherein the plurality of primary switches (111, 112, . . . ) are arranged in a full bridge arrangement.

9. The current booster circuitry (100) of of claim 1, wherein said plurality of secondary switches (131, 132, 133, 134) and/or said plurality of primary switches (111, 112) are provided as transistors, preferably FET transistors.

10. The current booster circuitry (100) of claim 1, wherein the transformer (120) comprises a core (125), preferably a ferrite core (125).

11. A printed circuit board assembly (200) comprising a multi-layer printed circuit board, PCB, (210), the PCB (210) comprises a current booster circuitry (100) according to claim 1 and a through hole (215) penetrating all layers of the PCB (210); wherein
said at least one primary winding (122) and said at least two secondary windings (126a, 126b) of the transformer (120) are routed around the through hole (215).

12. The printed circuit board assembly (200) of claim 11, wherein at least one of the secondary windings (126a, 126b) of the transformer (120) of the current booster circuitry (100) is arranged in an internal layer of the PCB (210).

13. The printed circuit board assembly (200) of claim 11, wherein the transformer (120) of the current booster circuitry (100) comprises one or two primary windings (122), wherein at least one of said one or two primary windings (122) is arranged in an outer layer (212, 214) of the PCB (210).

14. A current booster assembly (300) comprising a plurality of printed circuit board assemblies (200) according to claim 11, wherein said at least two input terminals (142, 144) of the primary windings (122) of the printed circuit board assemblies (200) are connected in series and said at least two output terminals (146, 148) of the printed circuit board assemblies (200) are connected in parallel.

15. The current booster assembly (300) of claim 14, wherein the through holes (215) of said plurality of printed circuit board assemblies (200) are aligned and a transformer core (125) is arranged though the through holes (215) of said plurality of printed circuit board assemblies (200).

16. A current booster system (400), comprising one or more current booster assemblies (300) according to claim 14, a carrier (410) provided with a plurality of sockets (412), wherein each printed circuit board assembly (200), of said one or more current booster assemblies (300), is arranged in an associated socket (412) of the carrier (410), and the parallel connection of said at least two output terminals (146, 148) of the printed circuit board assemblies (200) is provided by the carrier (410).

17. The current booster system (400) of claim 16, wherein the carrier (410) further comprises a primary side electric circuitry (110) operatively connected in parallel across the series connection of the input terminals (142, 144) of the printed circuit board assemblies (200), of said one or more current booster assemblies (300).

18. The current booster system (400) of claim 16, further comprising a control module (600) for controlling at least the secondary side electric circuitry (130) of the printed circuit board assemblies (200) of said one or more current booster assemblies (300).

19. A test equipment (500) for electrical test or measurement comprising one or more current booster circuitry (100) according to claim 1.
